(19) United States
(12) Patent Application Publication
(10) Pub. No.: US 2014/0009874 A1
(43) Pub. Date: Jan. 9, 2014

(54) COLLAPSIBLE ELECTRONIC EQUIPMENT

(71) Applicant: ACER INCORPORATED, Hsichih (TW)

(72) Inventor: Kai-Hung HUANG, Hsichih (TW)

(73) Assignee: ACER INCORPORATED, Hsichih (TW)

(21) Appl. No.: 13/744,875

(22) Filed: Jan. 18, 2013

(30) Foreign Application Priority Data
Jul. 9, 2012 (TW) 101124577

(51) Int. Cl. G06F 1/16; H05K 7/00

(52) U.S. Cl. CPC G06F 1/1681; H05K 7/00
USPC 361/679.01; 16/354

(57) ABSTRACT

A collapsible electronic equipment includes a first part, a hinge device, and a second part. The first part pivots on the second part via the hinge device. When the second part is inclined at an inclined angle relative to the first part, a shaft of the hinge device is moved from a first position to a second position.

### CROSS-REFERENCE TO RELATED APPLICATIONS

This Application claims priority of Taiwan Patent Application No. 101124577, filed on Jul. 9, 2012, the entirety of which is incorporated by reference herein.

### BACKGROUND OF THE INVENTION

1. Field of the Invention

The present invention relates to an electronic equipment, and in particular, to a collapsible electronic equipment.

2. Description of the Related Art

In recent years, since touch displays are very popular, users are accustomed to controlling electronic equipment by touching. Thus, many notebook computers are provided with touch functions via touch displays, such as rotatable touch displays.

However, a conventional hinge of the notebook computer does not allow the touch display to rotate to the rear side of a mainframe thereof Thus, in the conventional art, a dual-axis hinge is utilized to allow the touch display to rotate to a rear side of the mainframe. However, the structure of the dual-axis hinge is very complex, and the manufacturing cost is high. Moreover, the process of the display rotating to a rear side of the mainframe is not smooth, hindering usage of the notebook computer.

### BRIEF SUMMARY OF THE INVENTION

To solve the problems of the prior art, the object of the present invention provides a collapsible electronic equipment with a hinge device. The structure of the hinge device is simple, and a display of the collapsible electronic equipment is rotated smoothly to a rear side of a mainframe thereof.

The present invention provides a collapsible electronic equipment including a first part, a hinge device and a second part. The first part may be a mainframe, and the second part may be a display. The first part has a front surface and a rear surface opposite to the front surface. The hinge device includes a driving mechanism, a shifting mechanism, and a shaft. The driving mechanism is disposed on the first part. The shifting mechanism is disposed on the driving mechanism. The driving mechanism is for driving the shifting mechanism. The shaft is pivoted on the shifting mechanism. The second part is disposed on the shaft, and is rotatable relative to the first part.

When the second part covers the front surface, the shifting mechanism and the shaft are located at a first position. When the second part is located at an inclined position with an inclined angle relative to the first part, the driving mechanism drives the shifting mechanism to force the shaft to move from the first position to a second position, or move from the second position to the first position. When the second part is located at a rear side, relative to the rear surface, of the first part, the shifting mechanism and the shaft are located at the second position.

In conclusion, the structure of the hinge device of the collapsible electronic equipment is simple, and thus the manufacturing cost is decreased. Moreover, the display is rotated smoothly, making the collapsible electronic equipment more convenient to use.

### BRIEF DESCRIPTION OF THE DRAWINGS

The invention can be more fully understood by reading the subsequent detailed description and examples with references made to the accompanying drawings, wherein:

FIG. 1 is a perspective view of a collapsible electronic equipment according to the present invention;

FIG. 2 is a perspective view of a hinge device according to the present invention;

FIG. 3 is a exploded view of the hinge device according to the present invention;

FIG. 4 is a cross-sectional view of the collapsible electronic equipment according to the present invention; and

FIGS. 5 to 7 are schematic view of the collapsible electronic equipment in a moving process according to the present invention.

### DETAILED DESCRIPTION OF THE INVENTION

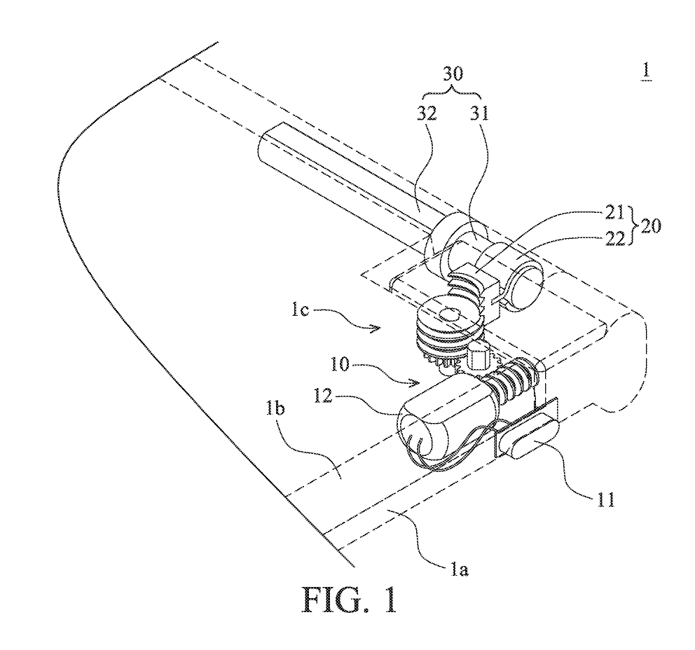

FIG. 1 is a perspective view of a collapsible electronic equipment 1 according to the present invention. The collapsible electronic equipment 1 may be a notebook computer. The collapsible electronic equipment 1 includes a first part 1a, a second part 1b, and a hinge device 1c. The first part 1a may be a mainframe including electronic elements, such as a keyboard, a touch panel, a touch display, a central processing unit (CPU), a memory, and a motherboard. The second part 1b may be a display, such as a touch display. The hinge device 1c is disposed on the first part 1a and the second part 1b, and the second part 1b is rotatable relative to the first part 1a via the hinge device 1c.

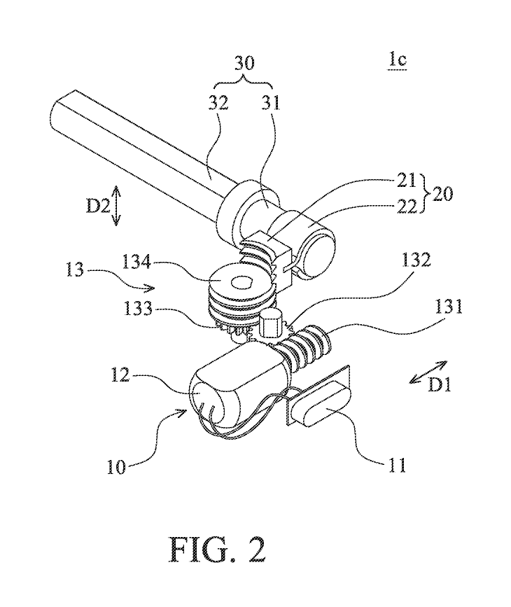

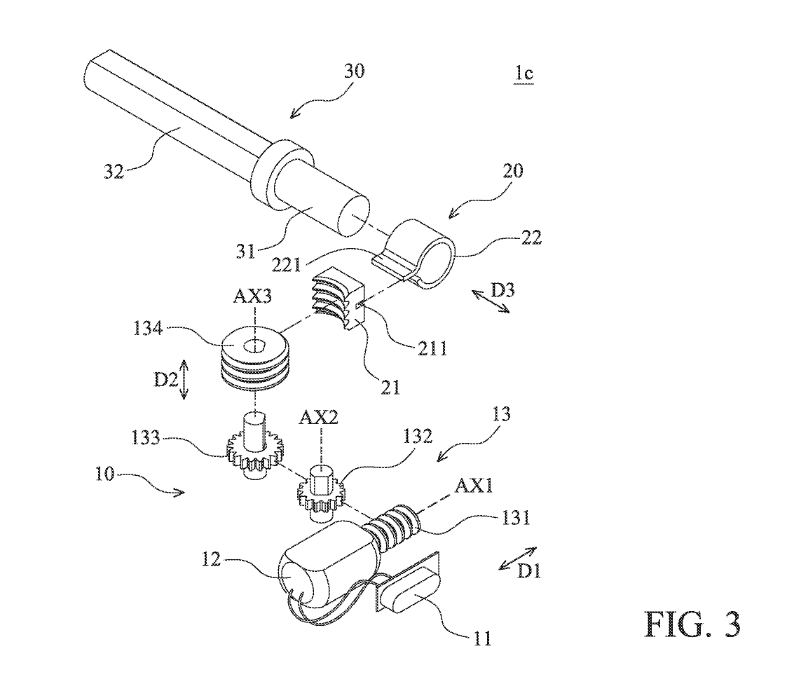

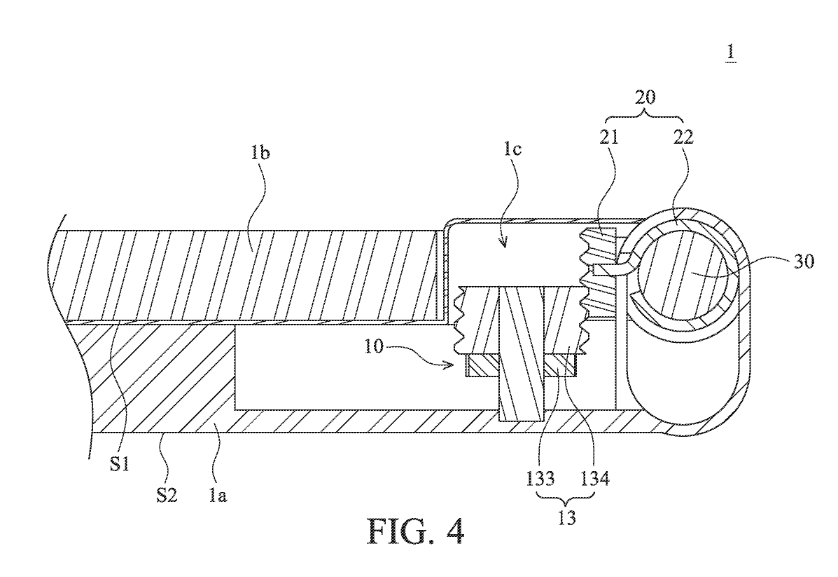

FIG. 2 is a perspective view of a hinge device 1c according to the present invention. FIG. 3 is an exploded view of the hinge device 1c according to the present invention. FIG. 4 is a cross-sectional view of the collapsible electronic equipment 1 according to the present invention. The hinge device 1c includes a driving mechanism 10, a shifting mechanism 20, and a shaft 30. The driving mechanism 10 is disposed on the first part 1a. The shifting mechanism 20 is movable disposed on the driving mechanism 10. The shaft 30 is pivoted on the shifting mechanism 20. The second part lb is fixed on the shaft 30, and rotatable relative to the first part 1a via the shaft 30.

The driving mechanism 10 includes a switch 11, a motor 12, and a gear set 13. The switch 11 is coupled to the motor 12. The switch 11 generates a switch signal according to a touching event. The motor 12 is enabled in forward or reverse rotation according to the switch signal, and drives the gear set 13 to rotate. The touching event may be generated by a user pressing the switch 11.

In another embodiment, the switch 11 may be excluded. For example, the motor 12 is controlled by a processing chip (not shown in figures) of the collapsible electronic equipment 1 which detects an inclined angle between the second part 1b and the first part 1a.

The gear set 13 includes a first worm gear 131, a first spur gear 132, a second spur gear 133, and a second worm gear 134. The first worm gear 131 is connected with the motor 12, and rotated about an axis AX1. The axis AX1 is extended along a first direction D1. The first spur gear 132 is engaged with the first worm gear 131, and is rotated about an axis AX2. The second spur gear 133 is engaged with the first spur gear 132, and is rotated about an axis AX3. The second worm gear 134 and second spur gear 133 have the same axis, and the second worm gear 134 is engaged with the shifting mechanism 20. The axis AX2 and axis AX3 are extended along a second direction D2, and the first direction D1 is perpendicular to the second direction D2.

By the described structure of the gear set 13, the driving mechanism 10 is able to be disposed in a thin collapsible electronic equipment. However, the gear set 13 has various embodiments, and the present invention is not limited by the described gear set 13.

The shifting mechanism 20 includes a gear rack 21 and a fixing element 22. The gear rack 21 is engaged with the second worm gear 134 of the gear set 13, and may be moved up or down along the second direction D2. The gear rack 21 has a fixing groove 211. The fixing element 22 is a ring structure, and pivoted on the shaft 30. The fixing element 22 has a retaining portion 221 fixed in the fixing groove 211 of the gear rack 21.

The shaft 30 includes a pivot portion 31 and a fixing portion 32 disposed on the pivot portion 31. The pivot portion 31 and the fixing portion 32 are extended along a third direction D3. The first direction D1, the second direction D2 and the third direction D3 are perpendicular to each other. The second part 1b is fixed on fixing portion 32, and the fixing element 22 is disposed and pivoted on the pivot portion 31. Thus, the second part 1b is rotatable relative to the first part 1a.

In the embodiment, when the motor 12 is enabled in forward rotation, the gear rack 21 is moved up along the second direction D2, and the shifting mechanism 20 and the shaft 30 are located at a first position. When the motor 12 is enabled in reverse rotation, the gear rack 21 is moved down along the second direction D2, and the shifting mechanism 20 and the shaft 30 are located at a second position. A mechanism, which controls the motor 12 enabled in forward or reverse rotation or disabled, is well known in this art, and the detailed descriptions thereof are not provided.

As shown in FIG. 4, the first part 1a has a front surface S1, and a rear surface S2 opposite to the front surface S1. When the second part 1b covers to the front surface S1 at a covering position, the shifting mechanism 20 and the shaft 30 are located at the first position. Thus, the second part 1b is able to cover the front surface S1 since the shaft 30 is protruding over the front surface S1.

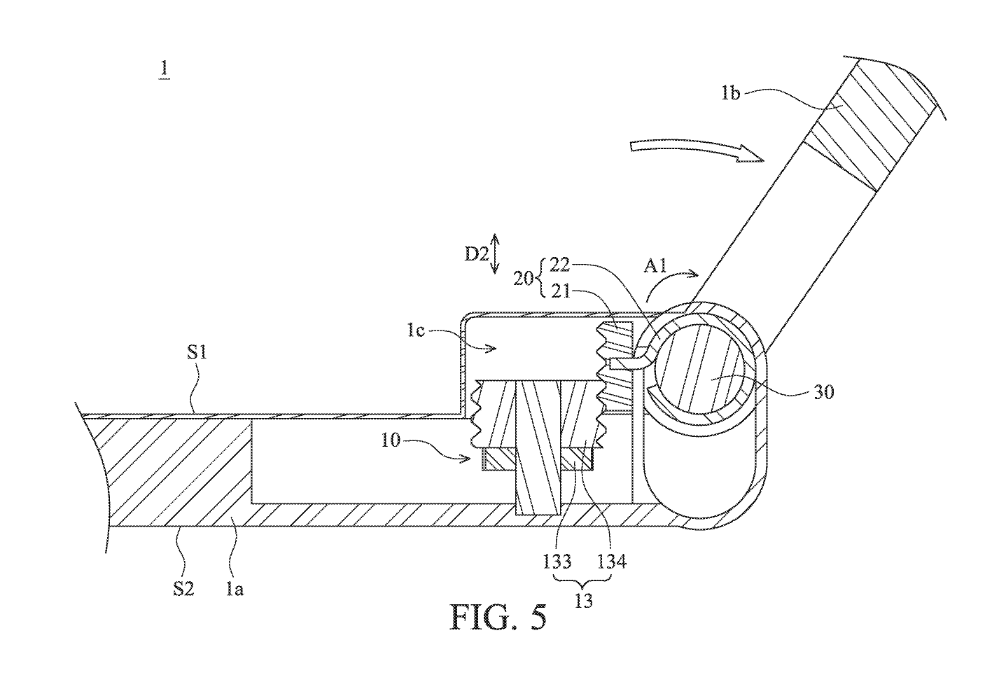

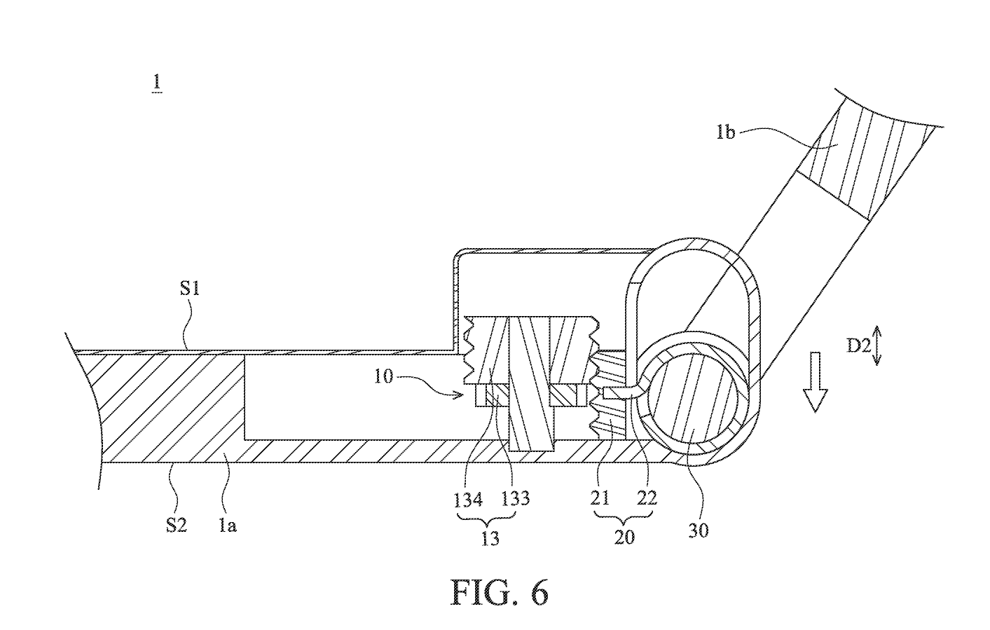

As shown in FIG. 5, when the second part 1b is located at an inclined position with an inclined angle A1 relative to the first part 1a, the shifting mechanism 20 and the shaft 30 are located at a first position. The collapsible electronic equipment 1 may be used as a notebook computer. Next, when the second part 1b is continuously rotated, the driving mechanism 10 may drive the shifting mechanism 20 to force the shaft 30 to move from the first position to the second position (as shown in FIG. 6). In the embodiment, the inclined angle A1 is between 90 degrees to 270 degrees.

Specifically, when the second part 1b is moved from the covering position to the inclined position, the driving mechanism 10 is enabled, and the second worm gear 134 of the driving mechanism 10 is rotated. Next, the second worm gear 134 moves the gear rack 21 of the shifting mechanism 20 down along the second direction D2, and the fixing element 22 and the shaft 30 is moved from the first position to the second position.

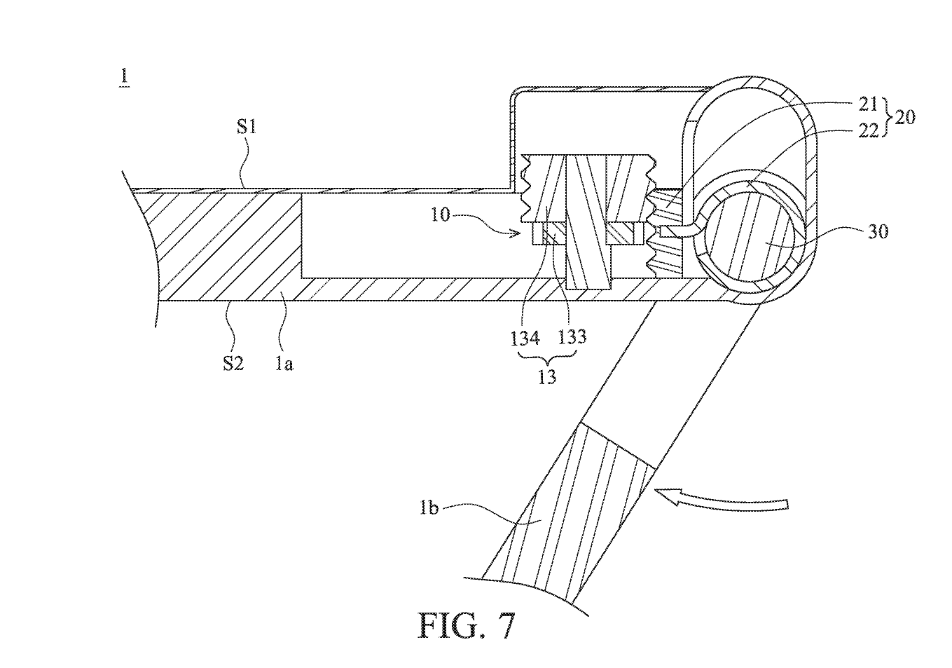

As shown in FIGS. 6 and 7, when the shifting mechanism 20 and the shaft 30 are located at the second position, the shaft 30 is protruded over or close to the rear surface S2, and the second part 1b is able to rotate to cover the rear surface S2 of the first part 1a. The collapsible electronic equipment 1 may be used as a tablet computer. Alternately, the second part 1b may be located at a rear position (at a rear side of the first part 1a as shown in FIG. 7), and then the front surface S1 of the first part 1a may be disposed on a surface, such as tabletop for convenience of operating the second part 1b. The rear side is relative to the rear surface S2, and a front side of the first part 1a is relative to the front surface S1.

Similarly, when the second part 1b is moved from the covering position (as shown in FIG. 4) or the rear position (as shown in FIG. 7) to the inclined position with the inclined angle Al as shown in FIG. 5 (or with another inclined angle between 90 degrees and 270 degrees), the driving mechanism 10 is enabled, and the second worm gear 134 of the driving mechanism 10 is rotated. Next, the second worm gear 134 drives the gear rack 21 of the shifting mechanism 20 to move up along the second direction D2, and thus the fixing element 22 and the shaft 30 is moved from the second position (as shown in FIG. 6) to the first position (as shown in FIG. 5).

Since the first part 1a and the second part 1b are pivoted with one shaft 30, the second part 1b is smoothly rotated relative to the first part 1a.

In another embodiment, the driving mechanism 10 and the shifting mechanism 20 may be further simplified. For example, some elements of the gear set 13, the switch 11 and the motor 12 of the driving mechanism 10, and the gear rack 21 of the shifting mechanism 20 may be excluded. The driving mechanism 10 includes connecting rods, and the driving mechanism 10 is controlled manually to move the fixing element 22 of the shifting mechanism 20 to let the shifting mechanism 20 and the shaft 30 move up or down along the second direction D2.

In conclusion, the structure of the hinge device of the collapsible electronic equipment of the present invention is simple, and thus the manufacturing cost is decreased. Moreover, the display is rotated smoothly, making the collapsible electronic equipment more convenient to use.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A collapsible electronic equipment, comprising:
a first part having a front surface;
a hinge device, comprising:
a driving mechanism disposed on first part;
a shifting mechanism disposed on the driving mechanism, wherein the driving mechanism is for driving the shifting mechanism; and
a shaft pivoted on the shifting mechanism; and
a second part, disposed on the shaft, rotatable relative to the first part via the shaft,
wherein when the second part is coved on the front surface, the shifting mechanism and the shaft are located at a first position, and
wherein when the second part is located at an inclined position with an inclined angle relative to the first part, the driving mechanism drives the shifting mechanism to force the shaft to move from the first position to a second position, or move from the second position to the first position.

2. The collapsible electronic equipment as claimed in claim 1, wherein the inclined angle is between 90 degrees and 270 degrees.

3. The collapsible electronic equipment as claimed in claim 1, wherein the first part has a rear surface opposite to front surface, and when the second part is located at a rear side, relative to the rear surface, of the first part, the shifting mechanism and the shaft are located at the second position.

4. The collapsible electronic equipment as claimed in claim 1, wherein the first part has a rear surface opposite to the front surface, and when the shaft is located at the first position, the shaft is protruded over the front surface, and when the shaft is located at the second position, the shaft is close to the rear surface.

5. The collapsible electronic equipment as claimed in claim 1, wherein the driving mechanism includes a motor and a gear set, and the motor drives the gear set rotating.

6. The collapsible electronic equipment as claimed in claim 5, wherein the driving mechanism further comprises a switch coupled to the motor.

7. The collapsible electronic equipment as claimed in claim 5, wherein the shifting mechanism further comprises a gear rack and a fixing element, and the gear rack is engaged with the gear set, and the fixing element is disposed on the gear rack and is pivoted on the shaft.

8. The collapsible electronic equipment as claimed in claim 7, wherein the gear set comprises:
a first worm gear connected with the motor;
a first spur gear engaged with the first worm gear;
a second spur gear engaged with the first spur gear; and
a second worm gear engaged with the gear rack, wherein the second worm gear and the second spur gear have the same axis.

9. The collapsible electronic equipment as claimed in claim 1, wherein the first part is a mainframe, and the second part is a display.
